(19) United States
(12) Patent Application Publication
(10) Pub. No.: US 2025/0231244 A1
(43) Pub. Date: Jul. 17, 2025

(54) WIRELESS ACQUISITION DEVICE AND METHOD FOR BATTERY SAFETY MONITORING OF BATTERY CLUSTER

(71) Applicant: Shenzhen Kemin Sensor Co., Ltd., Shenzhen (CN)

(72) Inventors: Weiting KONG, Shenzhen (CN); Gang WANG, Shenzhen (CN); Qiang ZENG, Shenzhen (CN)

(73) Assignee: Shenzhen Kemin Sensor Co., Ltd., Shenzhen (CN)

(21) Appl. No.: 19/026,047

(22) Filed: Jan. 16, 2025

(30) Foreign Application Priority Data
Jan. 17, 2024 (CN) 202410065945.5

(51) Int. Cl. G01R 31/371; G01R 31/374; G01R 31/3842; G01R 31/396; H01M 10/42; H01M 10/48; H01M 50/209; H01M 50/249; H01M 50/51

(52) U.S. Cl. CPC G01R 31/371; G01R 31/374; G01R 31/3842; G01R 31/396; H01M 10/425; H01M 10/482; H01M 10/486; H01M 50/209; H01M 50/249; H01M 50/51; H01M 2010/4271; H01M 2010/4278; H01M 2220/20

(57) ABSTRACT

Provided are wireless acquisition device and method for battery safety monitoring of a battery cluster. The device includes a wireless acquisition side, and a wireless reception side. The wireless acquisition side is fixedly arranged on a single battery in a battery module box, and both ends of the wireless acquisition side are electrically and respectively connected to a cathode and an anode of the single battery where the wireless acquisition side is located, and configured to acquire a temperature, a voltage and a current of a battery cell, an atmospheric pressure in the battery module box, and gas composition in a sealed space. The wireless reception side is configured to receive data collected by the wireless acquisition side through wireless transmission, perform edge data processing on the data, and then transmit the data to a battery thermal management system.

### CROSS-REFERENCE TO RELATED APPLICATION

This patent application claims the benefit and priority of Chinese Patent Application No. 202410065945.5 filed with the China National Intellectual Property Administration on Jan. 17, 2024, the disclosure of which is incorporated by reference herein in its entirety as part of the present application.

### TECHNICAL FIELD

The present disclosure relates to the technical field of battery safety monitoring, and in particular to a wireless acquisition device and method for battery safety monitoring of a battery cluster.

### BACKGROUND

The power batteries and energy storage batteries for new energy vehicles are often ternary lithium batteries and lithium iron phosphate batteries in China. In the case of thermal failure, these batteries show expansion, bulging and electrolyte leakage, which leads to battery explosion and combustion. Therefore, besides monitoring the voltage, current and temperature of the battery cell, it is crucial to monitor the safety pressure and electrolyte leakage of the whole battery pack.

The traditional battery management system (BMS) wiring harness only has the function of detecting the voltage, current and temperature of the battery cell, but each battery pack is composed of more than a dozen single batteries, and the voltage, current and temperature of each battery cell need to be monitored, which makes the whole wiring harness complicated in processing, difficult in processing technology, expensive in manufacturing cost, and difficult to assemble. The cost of manufacturing and assembling will be multiplied if the pressure and gas components added.

Usually, for cost reasons, the existing battery manufacturers only design monitoring points to monitor the voltage of each single battery cell, but reduce the monitoring points for monitoring the temperature of the cell. For example, a module composed of 24 batteries has more than 48 voltage acquisition points, but only 4-6 temperature acquisition points due to cost reasons, the temperature of each battery cell cannot be comprehensively monitored, leading to many security risks.

### SUMMARY

An objective of the present disclosure is to provide a wireless acquisition device and method for battery safety monitoring of a battery cluster, so as to solve the problems in the prior art. The temperature, voltage and current of each battery cell can be comprehensively monitored.

To achieve the objective above, the present disclosure provides the following technical solution.

The present disclosure provides a wireless acquisition device for battery safety monitoring of a battery cluster, including:
a wireless acquisition side, fixedly arranged on a single battery in a battery module box, where both ends of the wireless acquisition side are electrically and respectively connected to a cathode and an anode of the single battery where the wireless acquisition side is located, and configured to acquire a temperature, a voltage and a current of a battery cell of the single battery where the wireless acquisition side is located, an atmospheric pressure in the battery module box, and gas composition in a sealed space; and
a wireless reception side, configured to receive data collected by the wireless acquisition side through wireless transmission, perform edge data processing on the data, and then transmit data after the edge data processing to a battery thermal management system.

In an embodiment, multiple batteries are arranged in the battery module box in series. The wireless acquisition side includes a collector, a voltage acquisition flexible printed circuit (FPC) wire, and a FPC temperature sensor. The collector is fixedly arranged on the single battery in the battery module box. One end of the FPC temperature sensor is connected to the collector, and the other end of the FPC temperature sensor is welded to a cathode of the battery cell through a first metal terminal. One end of the voltage acquisition FPC wire is connected to the collector, and the other end of the voltage acquisition FPC wire is welded to an anode of the battery cell through a second metal terminal.

In an embodiment, the collector includes an upper cover of a plastic shell and a lower cover of the plastic shell which can be buckled and connected. The upper cover and the lower cover are both made of a plastic material, and conform to the use standard of vehicular plastic elements. An acquisition printed circuit board assembly (PCBA) module is fixedly arranged in a space formed between an inner side of the upper cover of the plastic shell and the lower cover of the plastic shell, and an integrated circuit is arranged on the acquisition PCBA module to be connected to a signal transmission chip, a voltage inspection chip, a first FPC connector and a second FPC connector. The first FPC connector is connected to the FPC temperature sensor, and the second FPC connector is connected to the voltage acquisition FPC wire.

In an embodiment, the FPC temperature sensor includes a first FPC, a first connecting finger, a temperature sensor, a first power conductor, a negative conductor of the temperature sensor, a positive conductor of the temperature sensor, a second sealant, and a first metal terminal. The temperature sensor is a thermosensitive element, including, but not limited to, a negative temperature coefficient (NTC) thermistor, a positive temperature coefficient (PTC) thermistor, a platinum resistor, a micro-electro-mechanical system (MEMS) temperature sensor, and a chip. The first metal terminal is made of nickel or copper-plated nickel, and the shape of the first metal terminal is not limited as long as the first metal terminal can be welded to the first FPC. The first FPC is provided with the first power conductor, the negative conductor of the temperature sensor, and the positive conductor of the temperature sensor. The temperature sensor is welded to the negative conductor of the temperature sensor and the positive conductor of the temperature sensor, and fixed to the first terminal by the second sealant. The first power conductor is welded to the first metal terminal, and sealed and fixed with the second sealant.

In an embodiment, the voltage acquisition FPC wire includes a voltage conductor, a second FPC, a second power conductor, a second connecting finger, a third connecting finger, a first sealant, and a second metal terminal. The second metal terminal is made of nickel or copper-plated nickel, and the shape of the second metal terminal is not limited as long as the second metal terminal can be welded to the second FPC. The second power conductor is connected to the second connecting finger and welded to the second metal terminal, and a welding position where the second power conductor is welded to the second metal terminal is sealed and fixed by the first sealant. The voltage conductor is connected to the third connecting finger and welded to the second metal terminal, and a welding position where the voltage conductor is welded to the second metal terminal is sealed and fixed by the first sealant.

In an embodiment, the upper cover of the plastic shell is provided with a first vent hole. An integrated circuit is arranged on the acquisition PCBA module to connect the signal transmission chip, the voltage inspection chip, a first pressure sensor, and gas composition monitoring sensor. The gas composition monitoring sensor includes a first hydrogen sensor, and a first carbon monoxide sensor. The gas composition monitoring sensor may be different gas sensors for single gas (including, but not limited to, carbon monoxide, carbon dioxide, hydrogen and volatile organic compounds (VOCs)) or an integrated sensor for sensing multiple gases.

In an embodiment, the wireless reception side includes an upper plastic cover, a lower plastic cover, and a reception PCBA module. An inner side of the lower plastic cover is provided with an integrally injection-molded metal pin, one end of the metal pin is connected to a welding hole formed in the reception PCBA module by tin soldering, and the other end of the metal pin is connected to a connector. A wiring harness connector is connected to the connector. The reception PCBA module is provided with an integrated circuit, and a signal transmission chip is connected to the integrated circuit. Two grooves are formed outside each of two side walls of the lower plastic cover, a square snap-fit protrusion is formed in a middle position in the groove, a fixing bracket is arranged between two grooves on the same side, and a circular through hole is formed in the fixing bracket. Two snap-fit brackets are arranged on each of two side walls of the upper plastic cover, and a square snap-fit hole is formed in each snap-fit bracket. The square snap-fit hole can be assembled with the corresponding square snap-fit protrusion. A wire is arranged on the wiring harness connector for communication of a received electrical signal.

In an embodiment, a second pressure sensor, a second hydrogen sensor and a second carbon monoxide sensor are connected to the integrated circuit arranged on the reception PCBA module. A second vent hole is formed in a front surface of the upper plastic cover.

The present disclosure provides a wireless acquisition method for battery safety monitoring of a battery cluster, including:
Step one, fixedly arranging a wireless acquisition side on a single battery, and electrically connecting both ends of the wireless acquisition side to a cathode and an anode of the single battery, respectively;
Step two, connecting multiple single batteries in series and then sealing the multiple single batteries in a battery module box, installing a wireless reception side in the battery module box together in the case that the battery module box is made of metal; and
Step three, supplying, by the battery, power to the wireless acquisition side, acquiring a temperature, a voltage and a current of each single battery cell in the battery module box, an atmospheric pressure in the battery module box and gas composition in a sealed space in real time; transmitting, by the wireless transmission, the data to the wireless reception side for edge data processing, and then transmitting the data to a battery thermal management system.

In an embodiment, in Step three, a data transmission form of each of the wireless acquisition side and the wireless reception side employs multi-transmission single-reception single-layer networking, or multi-transmission single-reception multi-layer networking.

The multi-transmission single-reception single-layer networking includes one wireless reception side, and multiple wireless acquisition sides, where the wireless reception side is able to receive data from the multiple wireless acquisition sides.

The multi-transmission single-reception multi-layer networking includes multiple wireless reception sides. One wireless reception side serves as a main wireless reception side, and the other wireless reception sides serve as slave wireless reception sides. The main wireless reception side is configured to receive the data from the multiple slave wireless reception sides, and each slave wireless reception side can receive data from the multiple wireless acquisition sides.

Compared with the prior art, the present disclosure has the following technical effects.

Through the wireless acquisition side to which power is supplied by the battery itself, the temperature, voltage and current of each battery cell in the battery box, the atmospheric pressure in the battery box and the gas composition in the sealed space are acquired in real time. The data is transmitted to the wireless reception side through wireless transmission for edge data processing, and then is transmitted to a battery thermal management system through wired connection of CAN2.0 protocol. By adopting wireless data transmission, the nonstandard characteristics and complexity of the traditional BMS sensing wiring harness are reformed, thereby achieving uniformity, standardization and simplification. The temperatures, voltages and currents of all battery cells in the battery pack/battery box, and the changes of atmospheric pressure and gas composition in the battery box can be monitored simultaneously. The monitoring is performed on the safe operation of the battery from physical and spatial dimensions. Data from multiple acquisition terminals are received at the same time, and the number of concurrencies is greater than 120. Data is acquired at low power consumption, the gas and pressure acquisition has sleep and wake-up functions. The transmission period is less than 100 ms, and the transmission distance is 10 m.

### BRIEF DESCRIPTION OF THE DRAWINGS

To describe the technical solutions of the embodiments of the present disclosure Embodiment: or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic structural diagram of a wireless acquisition side of a device according to the present disclosure;

FIG. 2 is a schematic structural diagram of a wireless acquisition side of a device according to the present disclosure from another perspective;

FIG. 3 is a schematic structural diagram of a wireless reception side of a device according to the present disclosure;

FIG. 4 is a schematic structural diagram of a wireless reception side of a device according to the present disclosure from another perspective;

FIG. 5 is a schematic diagram of a device according to the present disclosure installed on a battery;

FIG. 6 is a schematic diagram of a device according to the present disclosure when applied in a battery module;

FIG. 7 is a working principle diagram of the present disclosure;

FIG. 8 is a schematic diagram of multi-transmission single-reception single-layer networking according to the present disclosure;

FIG. 9 is a schematic diagram of multi-transmission single-reception multi-layer networking according to the present disclosure;

FIG. 10 is a schematic diagram of FIG. 5 from another perspective.

In the drawings: 1—first metal terminal; 2—first connecting finger; 3—temperature sensor; 4—first power conductor; 5—negative conductor of temperature sensor; 6—upper cover of plastic shell; 7—first FPC connector; 8—first FPC; 9—positive conductor of temperature sensor; 10—lower cover of plastic shell; 11—first signal transmission chip; 12—voltage inspection chip; 13—voltage conductor; 14—second FPC; 15—second FPC connector; 16—second power conductor; 17—second connecting finger; 18—third connecting finger; 19—first sealant; 20—second metal terminal; 21—second sealant; 22—plastic bone position; 23—first pressure sensor; 24—first hydrogen sensor; 25—first carbon monoxide sensor; 26—first vent hole; 27—acquisition PCBA module; 28—upper plastic cover; 29—snap—fit bracket; 30—lower plastic cover; 31—reception PCBA module; 32—second signal transmission chip; 33—groove; 34—square snap—fit protrusion; 35—fixing bracket; 36—circular through hole; 37—welding hole; 38—metal pin; 39—connector; 40—wiring harness connector; 41—square snap—fit hole; 42—second pressure sensor; 43—second hydrogen sensor; 44—second carbon monoxide sensor; 45—second vent hole; 46—battery; 47—anode of battery cell; 48—first welding position; 49—wireless acquisition side; 50—voltage acquisition FPC wire; 51—collector; 52—FPC temperature sensor; 53—wireless reception side; 5301—main wireless reception side; 5302—slave wireless reception side; 54—second welding position; 55—cathode of battery cell; 56—adhesive glue.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the scope of protection of the present disclosure.

An objective of the present disclosure is to provide a wireless acquisition device and method for battery safety monitoring of a battery cluster, so as to solve the problems in the prior art, which enables a comprehensive monitoring of the temperature, voltage and current of each battery cell.

In order to make the objectives, features and advantages of the present disclosure more clearly, the present disclosure is further described in detail below with reference to the accompanying drawings and specific embodiments.

### Embodiment 1

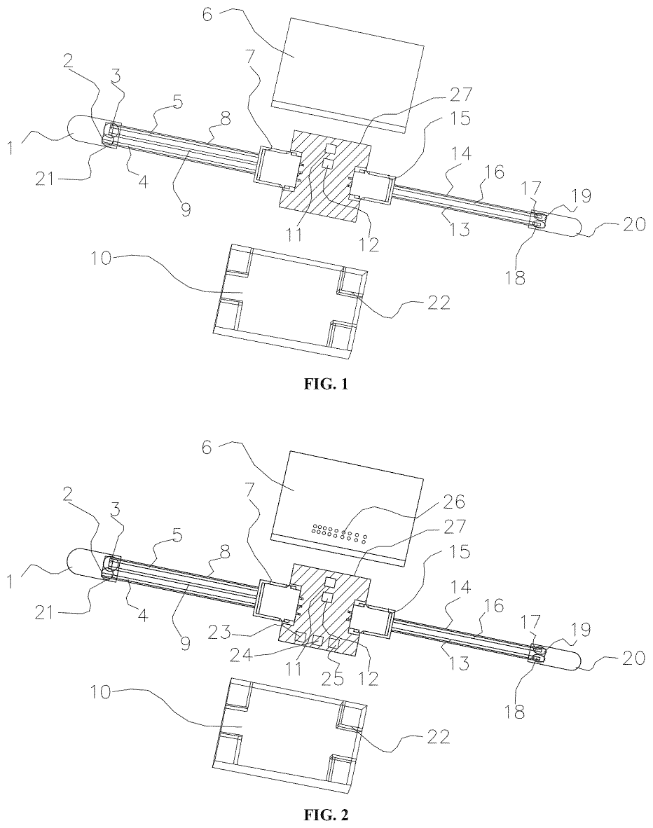

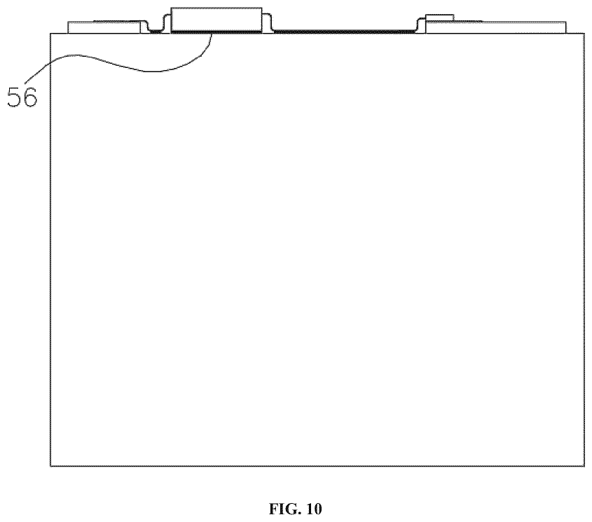

As shown in FIG. 1, FIG. 5 and FIG. 10, this embodiment provides a wireless acquisition device for battery safety monitoring of a battery cluster. The battery cluster is an entire composed of multiple battery units. Specifically, in this embodiment, the battery cluster is formed by arranging multiple batteries in series in a battery module box. In this embodiment, the wireless acquisition device for battery safety monitoring of a battery cluster includes a battery cluster, a wireless acquisition side 49, and a wireless reception side 53. The wireless acquisition side 49 is fixedly arranged on a single battery 46 in the battery module box, and both ends of the wireless acquisition side are respectively and electrically connected to a cathode and an anode of the single battery 46 where the wireless acquisition side is located, for acquiring a temperature, a voltage and a current of a cell of the single battery 46 where the wireless acquisition side is located, an atmospheric pressure in the battery module box, and gas composition in a sealed space. The wireless reception side 53 is configured to receive data collected by the wireless acquisition side 49 through wireless transmission, perform edge data processing on the data, and then transmit the data to a battery thermal management system. Specifically, the wireless acquisition side 49 includes a collector 51, a FPC temperature sensor 52, and a voltage acquisition FPC wire 50. One end of the FPC temperature sensor 52 is connected to the collector 51, and the other end of the FPC temperature sensor 52 is provided with a metal terminal to be welded to a cathode 55 of a battery cell arranged on the battery 46 at a second welding position 54. One end of the voltage acquisition FPC wire 50 is connected to the collector 51, and the other end of the voltage acquisition FPC wire 50 is provided with a metal terminal to be welded to an anode 47 of the battery cell at the first welding position 48. The collector 51 is fixed to the battery 46 by using an adhesive glue 56. The adhesive glue 56 is double-faced adhesive made of a cushioning material, or the collector 51 is directly fixed to the battery with an adhesive material.

According to the technical solution in this embodiment, through the wireless acquisition side 49 to which power is supplied by the battery 46, the temperature, voltage and current of each battery cell in the battery box, the atmospheric pressure in the battery box and the gas composition in the sealed space are acquired in real time. The data is transmitted to the wireless reception side 53 through wireless transmission for edge data processing, and then is transmitted to a battery thermal management system through wired connection of CAN2.0 protocol.

### Embodiment 2

This embodiment is a further improvement and perfection on the basis of Embodiment 1. In this embodiment, the wireless acquisition side 49 includes a collector 51, a voltage acquisition FPC wire 50, an FPC temperature sensor 52, and a first metal terminal 1 and a second metal terminal 20 made of pure nickel or aluminum or copper plated with nickel. The collector 51 includes an upper cover 6 of a plastic shell, a lower cover 10 of a plastic shell, an acquisition PCBA module 27, a first FPC connector 7, and a second FPC connector 15. The upper cover 6 of the plastic shell and the lower cover 10 of the plastic shell are both provided with plastic bone positions 22 for fixing the PCBA module 27. The acquisition PCBA module 27 is provided with an integrated circuit configured to connect a first signal transmission chip 11. The first signal transmission chip 11 is a 2.4 GHz-2.5 GHz communication chip or a wireless communication chip such as Bluetooth. The integrated circuit on the acquisition PCBA module 27 is also configured to connect a voltage inspection chip 12, the first FPC connector 7 and the second FPC connector 15. The first FPC connector 7 on the acquisition PCBA module 27 is connected to the FPC temperature sensor 52. The FPC temperature sensor 52 includes a first FPC 8, a first connecting finger 2, a temperature sensor 3, a first power conductor 4, a negative conductor 5 of the temperature sensor, a positive conductor 9 of the temperature sensor, a second sealant 21, and a first metal terminal 1. The temperature sensor 3 is a MEMS temperature sensor, or a thermistor such as a NTC thermistor and a PTC thermistor. The first FPC 8 is provided with a first power conductor 4, a negative conductor 5 of the temperature sensor, and a positive conductor 9 of the temperature sensor. The temperature sensor 3 is welded to the negative conductor 5 of the temperature sensor and the positive conductor 9 of the temperature sensor, and fixed to the first metal terminal 1 with the second sealant 21. The first power conductor 4 is welded to the first metal terminal 1 and sealed and fixed with the second sealant 21. The second FPC connector 15 arranged on the acquisition PCBA module 27 is connected to a voltage acquisition FPC wire 50. The voltage acquisition FPC wire 50 includes a voltage conductor 13, a second FPC 14, a second power conductor 16, a second connecting finger 17, a third connecting finger 18, a first sealant 19, and a second metal terminal 20. The second power conductor 16 is connected to the second connecting finger 17, welded to the second metal terminal 20, and sealed and fixed with the first sealant 19. The voltage conductor 13 is connected to the third connecting finger 18, welded to the second metal terminal 20, and sealed and fixed with the first sealant 19. The collector 51, after being assembled with the FPC temperature sensor 52 and the voltage acquisition FPC wire 50, is placed in a lower cover 10 of the plastic shell, and the acquisition PCBA module 27 is sealed with the sealant. When the sealant is cured, the upper cover 6 of the plastic shell and the lower cover 10 of the plastic shell are assembled.

As shown in FIG. 3, the wireless reception side 53 includes a reception PCBA module 31, a lower plastic cover 30, an upper plastic cover 28, a metal pin 38, a connector 39, and a wiring harness connector 40. The reception PCBA module 31 is provided with an integrated circuit to be connected to a second signal transmission chip 32, and is further provided with a welding hole 37 for connecting the metal pin 38. The lower plastic cover 30 is provided with an integrally injection-molded metal pin 38 to be connected to the welding hole 37 formed in the reception PCBA module by tin soldering. Two grooves 33 are formed outside each of two side walls of the lower plastic cover 30, a square snap-fit protrusion 34 is formed in the middle of each groove 33, a fixing bracket 35 is arranged at a position between the two grooves on the same side, and a circular through hole 36 is formed in the fixing bracket 35. Two snap-fit brackets 29 are formed on two side walls of the upper plastic cover 28, and a square snap-fit hole 41 is formed in the snap-fit bracket 29. The square snap-fit hole 41 is assembled with the square snap-fit protrusion 34. The wiring harness connector 40 is provided with a wire for the communication of a received electrical signal. Six welding holes 37 are formed in the reception PCBA module 31, and six metal pins 38 are correspondingly arranged on the lower plastic cover 30. The wiring harness connector 40 is provided with six communication wires, which are divided into power supply cathode, power supply anode, high level, low level, wake-up, and normal. The fixing bracket 35 and the circular through hole 36 are used to fix the wireless reception side 53 in a battery box cavity of a user.

### Embodiment 2

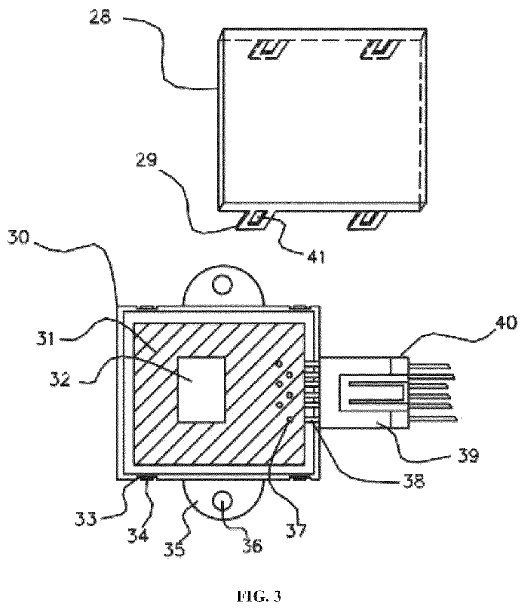

As shown in FIG. 2 and FIG. 5, this embodiment is a further optimization on the basis of Embodiment 2, the upper cover 6 of the plastic shell of the wireless acquisition side 49 is also provided with a first vent hole 26. The acquisition PCBA module 27 is provided with an integrated circuit to be connected to a first signal transmission chip 11, a voltage inspection chip 12, a first pressure sensor 23, a first FPC connector 7, a second FPC connector 15 and a gas component acquisition sensor. The gas component acquisition sensor includes a first hydrogen sensor 24 and a first carbon monoxide sensor 25. The first FPC connector 7 on the acquisition PCBA module 27 is connected to the FPC temperature sensor 52.

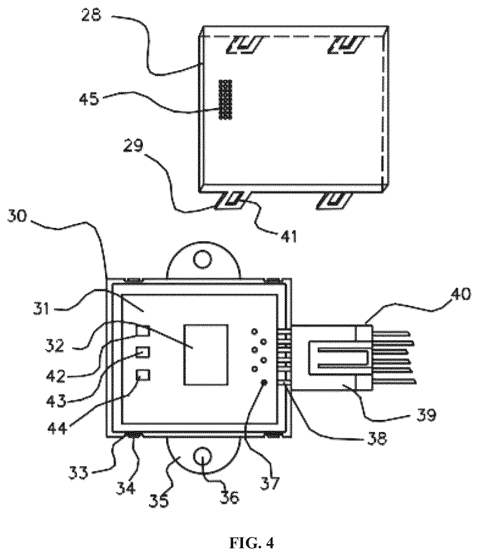

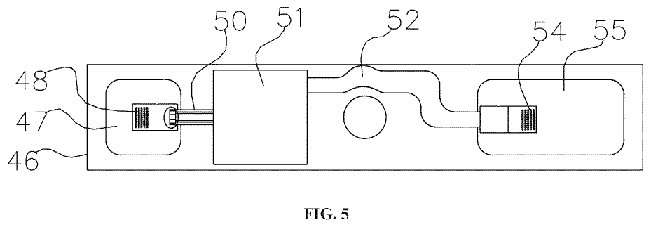

As shown in FIG. 4, the reception PCBA module 31 of the wireless reception side 53 in this embodiment is provided with an integrated circuit to be connected to a second signal transmission chip 32, a second pressure sensor 42, a second hydrogen sensor 43, and a second carbon monoxide sensor 44. The reception PCBA module is further provided with a welding hole 37 for connecting the metal pin 38. A second vent hole 45 is formed in a front surface of the upper plastic cover 28, and the second vent hole 45 plays a role in circulating air in the plastic shell, shape of which is not limited. The wiring harness connector 40 is provided with a wire for the communication of a received electrical signal. The wiring harness connector 40 is provided with six communication wires, which are divided into power supply cathode, power supply anode, high level, low level, wake-up, and normal.

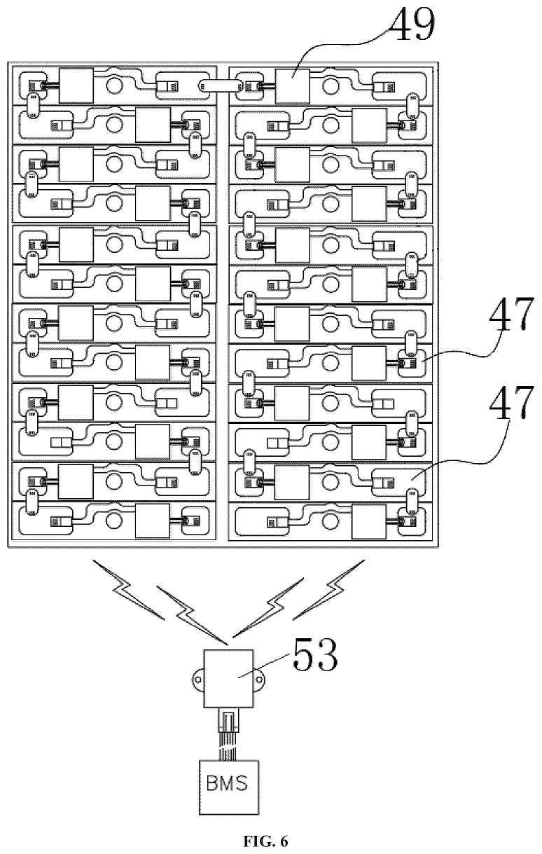

The present disclosure further provides a wireless acquisition method for battery safety monitoring of a battery cluster. As shown in FIG. 6, an example is a battery module composed of 24 single batteries connected in series. The 24 single batteries are integrated into one battery module box to form a battery cluster, and the wireless acquisition side 49 is installed on each battery 46. If the battery module box is made of metal, it is necessary to put the wireless reception side 53 together in the battery module box to transmit signals to the battery thermal management system through a communication cable.

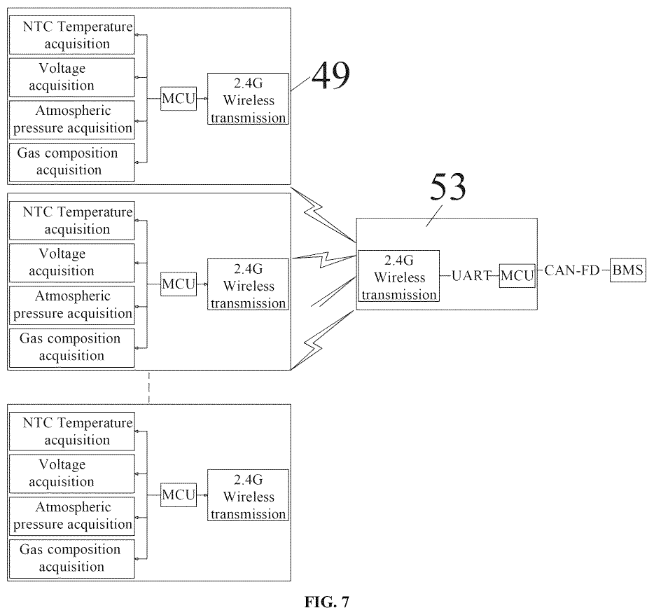

As shown in FIG. 7 which is a schematic diagram of a device according to the present disclosure, the symbols and notes referred to in FIG. 7 are all conventional technical terms in this art. Through the wireless acquisition side 49 to which the power is supplied by the battery 46 itself, the temperature, voltage and current of each battery cell in the battery box, the atmospheric pressure in the battery box and the gas composition in the sealed space are acquired in real time. The data is transmitted to the wireless reception side 53 through wireless transmission for edge data processing, and then is transmitted to a battery thermal management system.

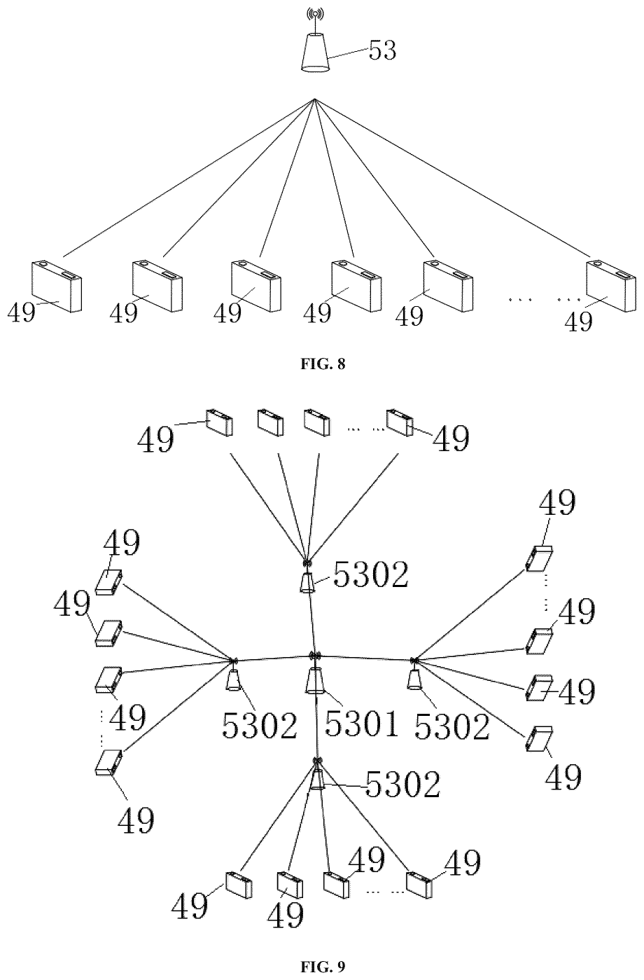

As shown in FIG. 8, a multi-transmission single-reception single-layer networking includes one wireless reception side 53, and multiple wireless acquisition sides 49. The wireless reception side 53 can receive the data from the multiple wireless acquisition sides. The network of multi-transmission single-reception single-layer networking is simple in structure, and the failure of a single sensor does not affect other sensors, so the multi-transmission single-reception single-layer networking is suitable for safety monitoring of power batteries of new energy vehicles.

As shown in FIG. 9, a multi-transmission single-reception multi-layer networking includes multiple wireless reception sides 53. One wireless reception side serves as a main wireless reception side 5301, and the other wireless reception sides serve as slave wireless reception sides 5302. The main wireless reception side 5301 is configured to receive the data from the multiple slave wireless reception sides, and each slave wireless reception side 5302 can receive data from the multiple wireless acquisition sides 49. The multi-transmission single-reception multi-layer networking may simultaneously increase the access of more acquisition sides, and concurrent interference is not easy to generate, so the multi-transmission single-reception multi-layer networking is suitable for safety monitoring of batteries in energy storage power station.

The noun BMS involved in the present disclosure is called power battery management system in Chinese, FPC is called flexible printed circuit in Chinese, and PCBA is called printed circuit board assembly in Chines, which all belong to the conventional technical terms familiar to those skilled in the art. The first connecting finger, the second connecting finger and the third connecting finger refer to metal contact points on the printed circuit board, which are usually located at the edge of the circuit board, and usually made of metal materials, such as gold, gold plating or gold alloy.

In the description of the present disclosure, it should be noted that the orientation or positional relationship indicated by terms “center”, “top”, “bottom”, “left”, “right”, “vertical”, “horizontal”, “inside” and “outside” is based on the orientation or positional relationship shown in the drawings only for convenience of description of the present disclosure and simplification of description rather than indicating or implying that the device or element referred to must have a particular orientation, be constructed and operate in a particular orientation, and thus are not to be construed as limiting the present disclosure. Furthermore, the terms “first” and “second” are used for descriptive purposes only and are not to be construed as indicating or implying relative importance.

Specific examples are used herein for illustration of the principles and embodiments of the present disclosure. The description of the embodiments is merely used to help illustrate the method and its core principles of the present disclosure. In addition, a person of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. A wireless acquisition device for battery safety monitoring of a battery cluster, comprising:
a wireless acquisition side, fixedly arranged on a single battery in a battery module box, wherein both ends of the wireless acquisition side are electrically and respectively connected to a cathode and an anode of the single battery where the wireless acquisition side is located, and configured to acquire a temperature, a voltage and a current of a battery cell of the single battery where the wireless acquisition side is located, an atmospheric pressure in the battery module box, and gas composition in a sealed space; and
a wireless reception side, configured to receive data collected by the wireless acquisition side through wireless transmission, perform edge data processing on the data, and then transmit data to a battery thermal management system.

2. The wireless acquisition device according to claim 1, wherein a plurality of batteries are arranged in the battery module box in series, the wireless acquisition side comprises an collector, a voltage acquisition flexible printed circuit (FPC) wire, and a FPC temperature sensor; the collector is fixedly arranged on the single battery in the battery module box; one end of the FPC temperature sensor is connected to the collector, and the other end of the FPC temperature sensor is welded to a cathode of the battery cell through a first metal terminal; and one end of the voltage acquisition FPC wire is connected to the collector, and the other end of the voltage acquisition FPC wire is welded to an anode of the battery cell through a second metal terminal.

3. The wireless acquisition device according to claim 2, wherein the collector comprises an upper cover of a plastic shell and a lower cover of the plastic shell which are able to be buckled and connected, an acquisition printed circuit board assembly (PCBA) module is fixedly arranged in a space formed between an inner side of the upper cover of the plastic shell and the lower cover of the plastic shell; and an integrated circuit is arranged on the acquisition PCBA module to connect a signal transmission chip, a voltage inspection chip, a first FPC connector and a second FPC connector; and the first FPC connector is connected to the FPC temperature sensor, and the second FPC connector is connected to the voltage acquisition FPC wire.

4. The wireless acquisition device according to claim 2, wherein the FPC temperature sensor comprises a first FPC, a first connecting finger, a temperature sensor, a first power conductor, a negative conductor of the temperature sensor, a positive conductor of the temperature sensor, a second sealant, and a first metal terminal; the first FPC is provided with the first power conductor, the negative conductor of the temperature sensor, and the positive conductor of the temperature sensor; the temperature sensor is welded to the negative conductor of the temperature sensor and the positive conductor of the temperature sensor, and fixed to the first metal terminal by the second sealant; and the first power conductor is welded to the first metal terminal, and sealed and fixed with the second sealant.

5. The wireless acquisition device according to claim 2, wherein the voltage acquisition FPC wire comprises a voltage conductor, a second FPC, a second power conductor, a second connecting finger, a third connecting finger, a first sealant, and a second metal terminal; the second power conductor is connected to the second connecting finger and welded to the second metal terminal, and a welding position where the second power conductor is welded to the second metal terminal is sealed and fixed with the first sealant; and the voltage conductor is connected to the third connecting finger and welded to the second metal terminal, and a welding position where the voltage conductor is welded to the second metal terminal is sealed and fixed with the first sealant.

6. The wireless acquisition device according to claim 3, wherein the upper cover of the plastic shell is further provided with a first vent hole; an integrated circuit is arranged on the acquisition PCBA module to connect the signal transmission chip, the voltage inspection chip, a first pressure sensor, a first hydrogen sensor, and a first carbon monoxide sensor.

7. The wireless acquisition device according to claim 1, wherein the wireless reception side comprises an upper plastic cover, a lower plastic cover, and a reception PCBA module; an inner side of the lower plastic cover is provided with an integrally injection-molded metal pin; one end of the metal pin is connected to a welding hole formed in the reception PCBA module by tin soldering, and an other end of the metal pin is connected to a connector; a wiring harness connector is connected to the connector; an integrated circuit is arranged on the reception PCBA module, and a signal transmission chip is connected to the integrated circuit; two grooves are formed outside each of two side walls of the lower plastic cover, a square snap-fit protrusion is formed in a middle position in the groove, a fixing bracket is arranged between two grooves on same side, and a circular through hole is formed in the fixing bracket; two snap-fit brackets are arranged on each of two side walls of the upper plastic cover, and a square snap-fit hole is formed in each snap-fit bracket; the square snap-fit hole is able to be assembled with corresponding square snap-fit protrusion; and a wire is arranged on the wiring harness connector for communication of a received electrical signal.

8. The wireless acquisition device according to claim 7, wherein a second pressure sensor, a second hydrogen sensor and a second carbon monoxide sensor are connected to the integrated circuit arranged on the reception PCBA module; and a second vent hole is formed in a front surface of the upper plastic cover.

9. A wireless acquisition method for battery safety monitoring of a battery cluster, comprising:
Step one, fixedly arranging a wireless acquisition side on a single battery, and electrically connecting both ends of the wireless acquisition side to a cathode and an anode of the single battery, respectively;
Step two, connecting a plurality of single batteries in series and then sealing the plurality of single batteries in a battery module box, installing a wireless reception side in the battery module box together in case that the battery module box is made of metal; and
Step three, supplying, by the battery, power to the wireless acquisition side, acquiring a temperature, a voltage and a current of each single battery cell in the battery module box, an atmospheric pressure in the battery module box and gas composition in a sealed space in real time; transmitting, by the wireless transmission, data to the wireless reception side for edge data processing, and then transmitting the data to a battery thermal management system.

10. The wireless acquisition method for battery safety monitoring of a battery cluster according to claim 9, wherein in Step three, a data transmission form of each of the wireless acquisition side and the wireless reception side employs multi-transmission single-reception single-layer networking, or multi-transmission single-reception multi-layer networking;
the multi-transmission single-reception single-layer networking comprises one wireless reception side, and multiple wireless acquisition sides, wherein the wireless reception side is able to receive data from the multiple wireless acquisition sides; and
the multi-transmission single-reception multi-layer networking comprises multiple wireless reception sides, wherein one wireless reception side serves as a main wireless reception side, and other wireless reception sides serve as slave wireless reception sides;
the main wireless reception side is configured to receive data from the multiple slave wireless reception sides, and
each slave wireless reception side is able to receive data from the multiple wireless acquisition sides.
